(19) United States
(12) Patent Application Publication
(10) Pub. No.: US 2014/0097018 A1
(43) Pub. Date: Apr. 10, 2014

(54) ELECTROMAGNETIC SHIELDED AIRCRAFT PASSENGER WINDOW

(71) Applicant: The Boeing Company, Chicago, IL (US)

(72) Inventor: Shawn P. Russell, Everett, WA (US)

(73) Assignee: The Boeing Company, Chicago, IL (US)

(21) Appl. No.: 14/011,237

(22) Filed: Aug. 27, 2013

Related U.S. Application Data
(60) Provisional application No. 61/712,207, filed on Oct. 10, 2012.

(51) Int. Cl. H05K 9/00; B32B 37/18

(52) U.S. Cl. CPC H05K 9/0066; B32B 37/18
USPC 174/389; 156/107

(57) ABSTRACT

Aircraft windows are constructed with a transparent layer having an embedded layer of electromagnetic radiation shielding material where the transparent layer of the window protects the layer of shielding material.

This patent application claims the benefit of the filing date of provisional patent application No. 61/712,207, filed on Oct. 10, 2012.

### FIELD

The present invention pertains to the construction of an aircraft window and in particular an aircraft passenger window. The aircraft window comprises a layer of electromagnetic shielding material and the construction of the aircraft window protects the layer of shielding material.

### BACKGROUND

Aircraft windows are at times constructed with shielding against electromagnetic radiation. Electromagnetic radiation can seriously damage the electronics system of an aircraft. The Aircraft windows are constructed with electromagnetic shielding to protect the aircraft electronics from being damaged by electromagnetic radiation passing through the windows.

Electromagnetic shielding materials typically employed in aircraft window constructions are very thin so as to not appreciably detract from the transparency of the aircraft window. With the shielding materials being very thin, they are also very delicate and can be easily damaged. The delicate nature of electromagnetic shielding materials contributes significantly to the complexity of constructing aircraft windows with electromagnetic shielding and increases the time required and the expense involved in constructing such windows.

### SUMMARY

The disadvantages associated with the construction of aircraft passenger windows that include electromagnetic radiation shielding are overcome by the aircraft passenger window of the invention. The aircraft window is comprised of a plurality of transparent layers, as is conventional. The materials employed in the plurality of transparent layers could include glass, acrylic, plastic, urethane, or other equivalent types of transparent materials.

To provide the aircraft window with electromagnetic shielding, one of the transparent layers has a layer of shielding material embedded in the layer. In one embodiment the shielding material is a grid or mesh of 50 OPI (openings per inch) stainless steel embedded in the interior of the one layer. The opposite surfaces of the layer of shielding material are covered by the one transparent layer. By encapsulating the layer of shielding material, the one transparent layer protects the embedded shielding material. The protection provided to the layer of shielding material substantially eliminates the potential for the shielding material being damaged during the window's construction and thereby reduces the time and cost involved in constructing the window.

The construction of the aircraft passenger window also includes an electrical conductor on the window peripheral edge that communicates electrically with the layer of electromagnetic shielding material. With the window installed on an aircraft, the electrical conductor electrically communicates with a portion of the aircraft to which the window is connected, for example the aircraft frame or fuselage. The electrical conductor thereby electrically communicates the layer of electromagnetic shielding material to the aircraft frame or fuselage. Electromagnetic radiation directed toward the aircraft window is intercepted by the layer of electromagnetic shielding material and the energy produced by the electromagnetic radiation is conducted from the layer of electromagnetic shielding material through the conductor and then to the aircraft frame or fuselage where the energy is dissipated.

In one embodiment of the aircraft passenger window a conductive material is employed in attaching the window to a portion of an aircraft. The conductive material extends around the peripheral edge of the window. A first portion of the conductive material contacts an exposed portion of the electromagnetic shielding material of the window. A second portion of the conductive material is coupled to a portion of an aircraft when attaching the window to the aircraft. The conductive material is also an electrical conductor and provides electric communication from the layer of electromagnetic shielding material, through the conductive material and to the portion of the aircraft to which the window is attached. Electromagnetic radiation directed toward the window is intercepted by the layer of electromagnetic shielding material and energy from the electromagnetic radiation is conducted through the conductive material to the portion of the aircraft to which the conductive material is coupled where the energy is dissipated.

In a further embodiment of the aircraft window a plurality of spring clips are employed in attaching the window to a portion of an aircraft. Each spring clip has a first portion that contacts an exposed portion of the electromagnetic shielding material of the window and a second portion that attaches to a portion of an aircraft when attaching the window to the aircraft. Each of the bonded spring clips is also an electrical conductor and provides electric communication between the layer of electromagnetic shielding material and the portion of the aircraft to which the spring clip is attached. Electromagnetic radiation directed toward the window is intercepted by the layer of electromagnetic shielding material in the window and energy from the electromagnetic radiation is conducted through the spring clips to the portion of the aircraft to which the spring clips are attached where the energy is dissipated.

The features, functions, and advantages that have been discussed can be achieved independently in various embodiments or may be combined in yet other embodiments further details of which can be seen with reference to the following description and drawings.

### BRIEF DESCRIPTION OF THE DRAWING FIGURES

FIG. 1 is a representation of a side elevation view of an aircraft employing the passenger window of the invention.

FIG. 2 is a partial sectioned view representing the construction of an embodiment of the passenger window.

FIG. 3 is a partial sectioned view of the window construction of FIG. 2 shown attached to a portion of an aircraft.

FIG. 4 is a representation of a cross-section of a further embodiment of the viewport window.

FIG. 5 is a representation of a cross-section of a further embodiment of the door viewport outer pane window.

FIG. 6 is a flow chart illustrating an embodiment of a method of assembling or manufacturing the aircraft window.

FIG. 7 is a flow chart illustrating an embodiment of a method of using the aircraft window.

FIG. 8 is a flow diagram of aircraft production and service methodology.

FIG. 9 is a block diagram of an aircraft.

### DETAILED DESCRIPTION

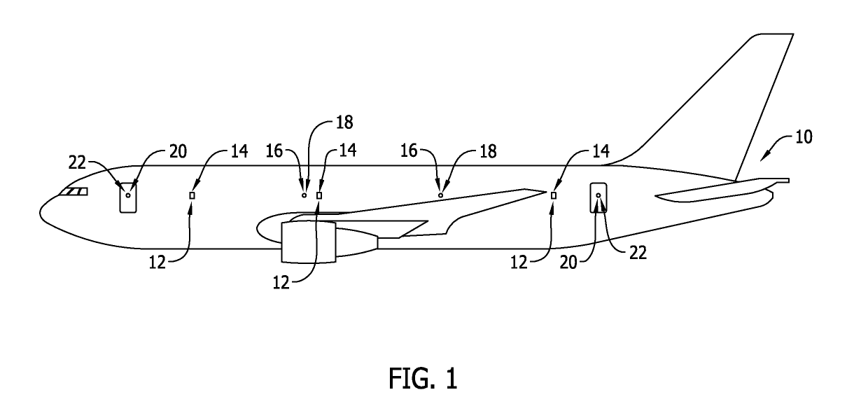

FIG. 1 is a representation of a side elevation view of an aircraft 10 employing the window constructions of the invention. In FIG. 1 the rounded, generally rectangular shaped bands 12 represent the peripheral edges of the aircraft passenger windows 14 of the invention constructed in accordance with the method of the invention. The general circular bands 16 represent the peripheral edges of aircraft viewport windows 18 constructed in accordance with the method of the invention. The generally circular bands 20 shown on the passenger doors represents the peripheral edges of the aircraft passenger door viewport windows 22 constructed in accordance with the method of the invention.

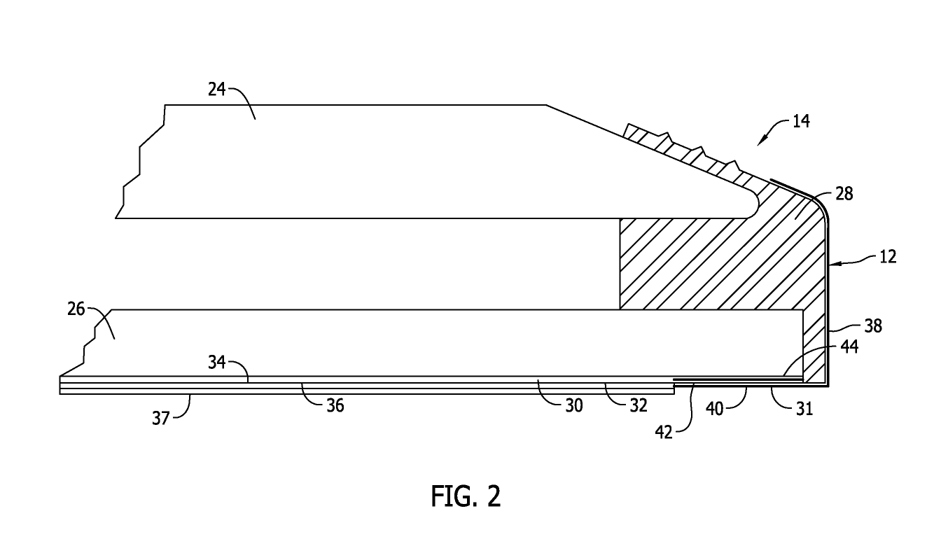

FIG. 2 is a partial, sectioned view representing the construction of the aircraft passenger window 14. The window 14 is basically constructed of a first transparent layer 24 and a second transparent layer 26. The materials employed in the two transparent layers 24, 26 could include glass, acrylic, plastic, urethane, or other equivalent types of transparent materials. In FIG. 2, the first transparent layer 24 is an outboard layer that faces the exterior of the aircraft 10 and the second transparent layer 26 is an inboard layer than faces the interior of the aircraft. The first layer 24 and the second layer 26 are coextensive across the window 14. The peripheral edges of the first layer 24 and the second layer 26 form a part of the construction of the peripheral edge 12 of the window 14.

A pressure seal 28 shown in cross-section in FIG. 2 extends around the peripheral edge 12 of the window 14. The pressure seal 28 seals the connection of the window 14 to the portion of the aircraft 10 to which the window is attached.

To provide the aircraft passenger window 14 with electromagnetic shielding, an additional transparent layer 30 is added to the window construction. The additional or third transparent layer 30 is positioned on the inboard side of the first 24 and second 26 transparent layers of the window and is also coextensive with the first 24 and second 26 transparent layers. The third transparent layer 30 could be constructed of the same transparent materials of the first 24 and second 26 transparent layers, or different materials. In the embodiment of the window shown in FIG. 2 the third transparent layer is constructed of urethane. Additionally, a peripheral edge 31 of the third transparent layer 30 coincides with the peripheral edge 12 of the window. This third transparent layer 30 has a layer of electromagnetic radiation shielding material 32 embedded in the layer.

The electromagnetic shielding material 32 in the third transparent layer 30 could be any known type of shielding material. In the embodiment represented in FIG. 2, the shielding material 32 is a grid or mesh of 50 OPI (openings per inch) stainless steel embedded in the urethane of the third layer 30. By being embedded, what is meant is that the layer of shielding material 32 is encapsulated inside the third transparent layer 30. The opposite surfaces 34, 36 of the layer of shielding material 32 are covered over by the urethane of the third transparent layer 30. With the urethane of the third transparent layer 30 encapsulating the layer of shielding material 32, the third transparent layer 30 protects the embedded shielding material. The protection provided to the layer of shielding material 32 substantially eliminates the potential for the shielding material being damaged during the construction of the window 14 and thereby reduces the time and cost involved in constructing the window.

A still further fourth transparent layer 37 is added to the window construction on the inboard side of the third transparent layer 30. The fourth transparent layer 37 could be constructed of the same transparent materials of the other layers or other transparent material. For example the transparent layers could be acrylic, polyurethane with the mesh encapsulated in the urethane and a hard urethane layer. The reverse arrangement of these layers could also be employed.

The construction of the aircraft passenger window 14 also includes an electrical conductor 38 that extends over the window peripheral edge 12. In the preferred embodiment of the window 14, the electrical conductor 38 extends completely around the window peripheral edge 12. Also in the preferred embodiment, the electrical conductor 38 is a foil tape, for example a tin plated copper tape. A portion of the electrical conductor 40 extends from the window peripheral edge 12 and contacts an exposed portion of the peripheral edge 42 of the shielding material 32. An additional strip of conductive material 44 contacts the exposed portion of the peripheral edge 42 of the shielding material on the opposite side of the shielding material from the electrical conductor portion 40. The connection of the electrical conductor portion 40 and the conductive material strip 44 to the exposed portion of the peripheral edge 42 of the shielding material 42 provides electrical communication between the layer of shielding material 32 and the electrical conductor 38. With the electrical conductor 38 being positioned on the window peripheral edge 12, when the window 14 is installed on an aircraft the electrical conductor 38 provides an electrically conductive coupling to the portion of the aircraft to which the window is attached, for example the aircraft metal frame or fuselage. The electrical conductor 38 thereby electrically communicates the layer of electromagnetic shielding material 32 to the aircraft frame or fuselage. Electromagnetic radiation directed toward the aircraft window 14 is intercepted by the shielding material 32 and the energy produced by the electromagnetic radiation is conducted from the layer of shielding material 32 through the electrical conductor 38 and then to the aircraft frame or fuselage where the energy is dissipated.

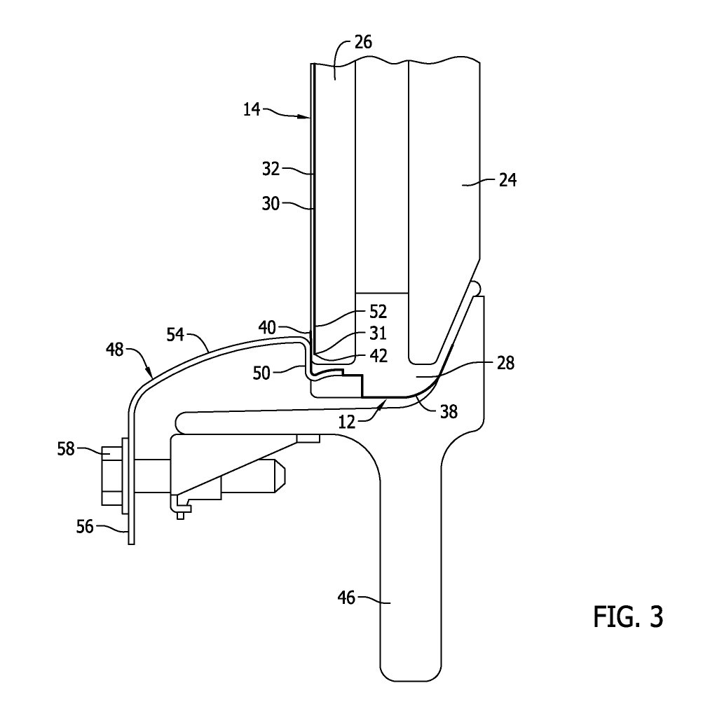

FIG. 3 is a representation of the aircraft passenger window 14 of FIG. 2 attached to a metal structural portion 46 of the aircraft. In FIG. 3 the electrical conductor 38 on the window peripheral edge 12 can be seen coupled to the aircraft structural portion 46, thereby establishing an electrical connection between the electromagnetic radiation shielding material 32 embedded in the window third transparent layer 30 with the portion of the aircraft structure 46 to which the window is attached.

Also shown in FIG. 3 is a representation of a spring clip 48 that is employed in attaching the window 14 to the metal structural portion 46 of the aircraft. Although only one spring clip 48 is shown in FIG. 3, in practice a plurality of spring clips 48 would be employed in attaching the window 14 to the portion of the aircraft 46. Each of the spring clips 48 is constructed of an electrically conductive material. Each spring clip 48 has a first portion or first end 50 having a bend. As represented in FIG. 3, the bent end 50 of the spring clip 48 is configured to extend around an exposed portion 52 of the electromagnetic shielding material on the inboard side of the third transparent layer 30 and around a portion of the electrical conductor 40. This contact connects the spring clip 48 in electric communication with the layer of shielding material 32 and the portion of the aircraft 46. The spring clip 48 also has a resilient intermediate portion 54 that extends from the first end or bent end 50 of the spring clip to a second end 56 of the spring clip. As represented in FIG. 3, the spring clip second end 56 is generally planar. The second end 56 is bent at an angle from the intermediate portion 54 to a position adjacent the portion of the aircraft structure 46 to which the window 14 is attached. The spring clip second end 56 has a hole that is dimensioned to receive a threaded fastener 58 that attaches the spring clip second end 56 and the spring clip 48 to the portion of the aircraft structure 46. The threaded fastener 58 is also electrically conductive. The fastener 58 therefore provides a portion of an electrically conductive path from the layer of shielding material 32 through the electrical conductor 38 and the spring clip 48 to the portion of the aircraft structure 46. The spring clip 48 is also constructed with ground studs (not shown) that provide primary paths of conductivity. The attachment of the spring clip second end 56 to the aircraft structural portion 46 by the threaded fastener 58 also produces a biasing force in the spring clip resilient intermediate portion 54. The biasing force causes the spring clip bent end 50 to exert a force on the window peripheral edge 12. This urges the pressure seal 28 against the aircraft structural portion 46 and with the other spring clips of the plurality of spring clips, securely holds the window 14 to the aircraft structural portion 46.

With the spring clips 48 attaching the window 14 to the aircraft structural portion 46, electromagnetic radiation directed toward the window is intercepted by the layer of the electromagnetic shielding material 32 in the window. Energy from the electromagnetic radiation is conducted through the spring clips 48 to the portion of the aircraft structure 46 to which the spring clips are attached where the energy is dissipated.

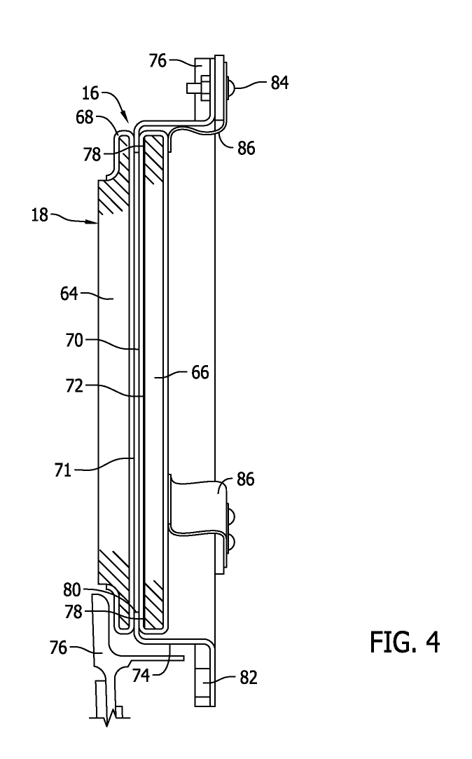

FIG. 4 is a representation of a cross-section of the aircraft passenger observation window 18. The observation window 18 has a construction similar to that of the passenger window 14. The observation window 18 also includes a first transparent layer 64 and a second transparent layer 66. The materials employed in the two transparent layers 64, 66 could basically be the same as those of the passenger window 14. In FIG. 4 the first transparent layer 64 is an outboard layer that faces the exterior of the aircraft and the second transparent layer 66 is an inboard layer that faces the interior of the aircraft. The first layer 64 and a second layer 66 are coextensive across the window 18. The peripheral edges of the first layer 64 and the second layer 66 form a part of the construction of the peripheral edge 16 of the window 18.

A pressure seal 68 shown in cross-section in FIG. 4 extends around the peripheral edge 16 of the observation window 18. As with the passenger window 14, the pressure seal 68 not only seals the connection of the window 18 to the portion of the aircraft 10 to which the window is attached, but also holds the first transparent layer 64 and the second transparent layer 66 in the relative positions.

To provide the observation window 18 with electromagnetic shielding, an additional transparent layer 70 is added to the window construction. However, unlike the passenger window 14, in the construction of the observation window 18 the third transparent layer 70 is positioned between the first 64 and second 66 transparent layers of the window. The third transparent layer 70 is also coextensive with the first 64 and second 66 transparent layers. The third transparent layer has a layer of electromagnetic radiation shielding material 72 embedded in the layer. The construction of the observation window third transparent layer 70 is basically the same as that of the third transparent layer 38 of the passenger window 14 and therefore will not be further described herein.

A still further fourth transparent layer 71 is added to the window construction on the outboard side of the third transparent layer. The fourth transparent layer 71 could be constructed of the same transparent materials of the other layers or other transparent material. For example the transparent layers could be acrylic, polyurethane with the mesh encapsulated in the urethane and a hard urethane layer. The reverse arrangement of these layers could also be employed.

Also shown in FIG. 4 is a representation of a cross-section of a retainer ring 74. The retainer ring 74 is employed in attaching the observation window 18 to a metal structural portion of an aircraft 76. The retainer ring 74 is also constructed of an electrically conductive material. The ring 74 extends around the peripheral edge 16 of the observation window 18. A first, annular portion 78 of the ring 74 is bent radially inwardly and extends over an exposed peripheral portion 80 of the electromagnetic shielding material 72 of the window. A second annular portion 82 of the retainer ring is bent radially outwardly. This second portion 82 of the ring has a plurality of fastener holes. A plurality of fastener assemblies 84 hold the inner pane viewport in place. There is no direct connection of the electromagnetic shielding material 72 and the aircraft frame. The shielding material 72 is grounded via capacitive coupling. Electromagnetic radiation directed toward the observation window 18 is intercepted by the layer of electromagnetic shielding material 72 and energy from the electromagnetic radiation is dissipated through the retainer ring 74.

In addition to the retainer ring 74, in FIG. 4 a plurality of spring clips 86 are also shown securing the observation window 18 to the retainer ring 74. The spring clips 86 have the same construction and function as the earlier described spring clip 48 and will not be further described herein.

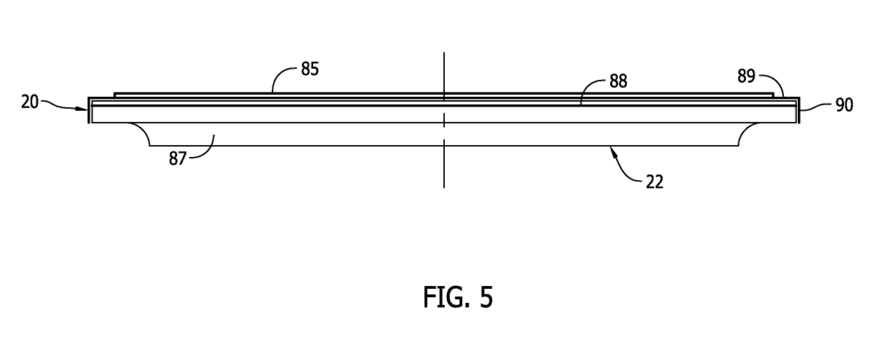

FIG. 5 is a representation of a cross-section of the aircraft passenger door observation window outer pane 22 constructed in accordance with the method of the invention. The passenger door observation window 22 is also constructed of a first transparent layer 87. The first 87 transparent layer could be constructed of the same materials of the previously described embodiments.

To provide the passenger door observation window 22 with the electromagnetic shielding, a second transparent layer 88 is added to the window construction. The second transparent layer is positioned on the inboard side of the first transparent layer 87. The second transparent layer 88 is constructed in the same manner as the third transparent layer of previous embodiments. The second transparent layer 88 has a layer of electromagnetic radiation shielding material 89 embedded in the layer. The shielding material 89 is basically the same as that previously described embodiments.

A still further third transparent layer 85 is added to the window construction overlaying the second transparent layer 88. The third transparent layer could be constructed of the same transparent materials of the other layers.

Also as in previously described embodiments, an electrical conductor 90 extends over the window peripheral edge 20. The electrical conductor 90 is basically the same as the previously described embodiments. The electrical conductor 90 extends around the window peripheral edge 20 and extends over an exposed peripheral portion of the shielding material 89 of the window. The electrical conductor 90 is sufficiently close to the shielding material 89 to capacitively couple the shielding material 89 to adjacent structure. This provides electrical communication between the layer of shielding material 89 and the electrical conductor 90. With the electrical conductor 90 being positioned on the window peripheral edge 20, the electrical conductor 90 provides an electrically conductive connection to the portion of the aircraft to which the window is attached, for example the aircraft metal frame or fuselage. The electrical conductor 90 thereby electrically communicates the layer of electromagnetic shielding material 89 to the aircraft frame or fuselage. Electromagnetic radiation directed toward the aircraft passenger door observation window 22 is intercepted by the shielding material 89 and the energy produced by the electromagnetic radiation is conducted from the layer of shielding material 89 through the electrical conductor 90 and then to the aircraft frame or fuselage where the energy is dissipated.

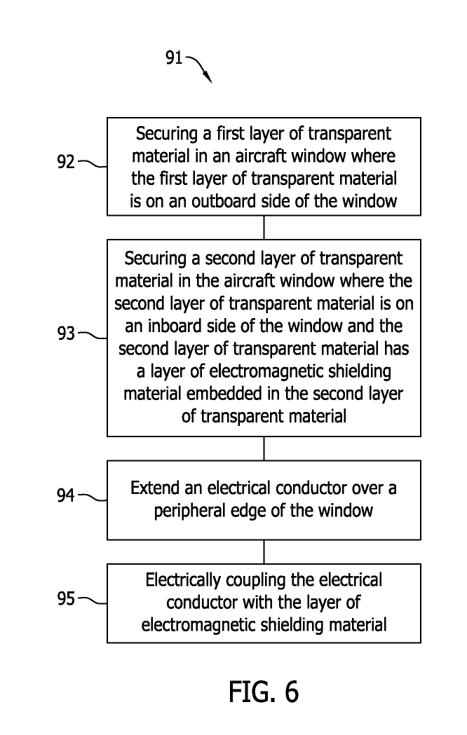

FIG. 6 is a flow chart of an embodiment of a method 91 of assembling or manufacturing the aircraft window 14. Basically, the method 91 of manufacturing the window may involve a step 92 of securing the first layer of transparent material 24 to the window 14 where the first layer of transparent material is on an outboard side of the window. The manufacturing method may also include a step 93 of securing an additional layer of transparent material 30 in the aircraft window where the additional layer of transparent material is on an inboard side of the window and the additional layer of transparent material has a layer of electromagnetic shielding material 32 embedded in the transparent material. Additionally, the method of manufacturing the window may include a step 94 of extending an electrical conductor over a peripheral edge of the window, and a further step 95 of electrically coupling the electrical conductor with the layer of electromagnetic shielding material.

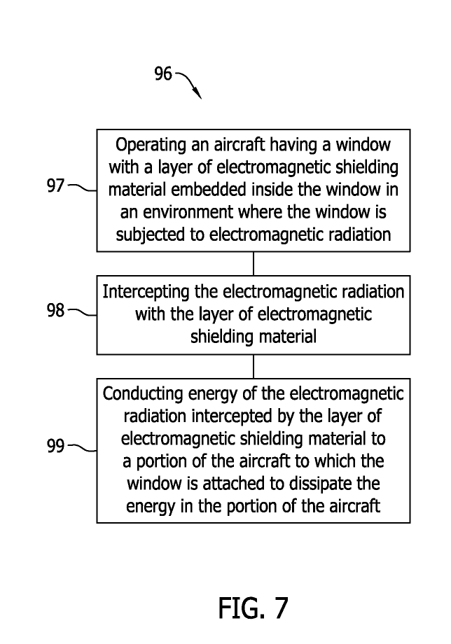

FIG. 7 is a flow chart 96 illustrating the earlier described steps involved in the method of using the aircraft window 14 to dissipate electromagnetic radiation directed at the window. The method 96 basically involves a step 97 of operating the aircraft 10 in an environment where the aircraft window 14 will be subjected to electromagnetic radiation. The method 96 also involves a step 98 of intercepting the electromagnetic radiation directed toward the aircraft window with the layer of electromagnetic shielding material 32 embedded in the window. In a further step 99 of the method 96 the energy generated by the electromagnetic radiation intercepted by the layer of electromagnetic shielding material is conducted to a portion of the aircraft to which the window is attached to dissipate the energy in the portion of the aircraft.

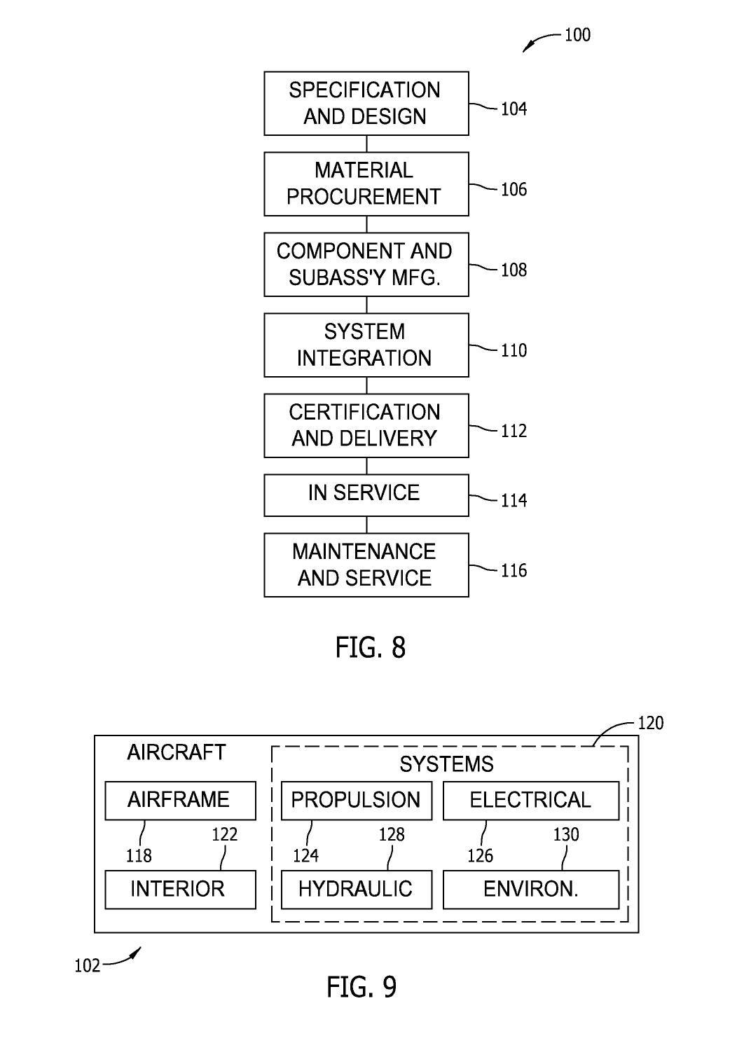

Referring to FIGS. 8 and 9, embodiments of the disclosure may be described in the context of an aircraft manufacturing and service method 100 as shown in FIG. 8 and an aircraft 102 as shown in FIG. 9. During pre-production, exemplary method 100 may include specification and design 104 of the aircraft 102 and material procurement 106. During production, component and subassembly manufacturing 108 and system integration 110 of the aircraft 102 takes place. Thereafter, the aircraft 102 may go through certification and delivery 112 in order to be placed in service 114. While in service by a customer, the aircraft 102 is scheduled for routine maintenance and service 116 (which may also include modification, reconfiguration, refurbishment, and so on).

Each of the processes of method 100 may be performed or carried out by a system integrator, a third party, and/or an operator (e.g., a customer). For the purposes of this description, a system integrator may include without limitation any number of aircraft manufacturers and major-system subcontractors; a third party may include without limitation any number of venders, subcontractors, and suppliers; and an operator may be an airline, leasing company, military entity, service organization, and so on.

As shown in FIG. 9, the aircraft 102 produced by exemplary method 100 may include an airframe 118 with a plurality of systems 120 and an interior 122. Examples of high-level systems 120 include one or more of a propulsion system 124, an electrical system 126, a hydraulic system 126, and an environmental system 130. Any number of other systems may be included. Although an aerospace example is shown, the principles of the invention may be applied to other industries, such as the automotive industry.

Apparatus and methods embodied herein may be employed during any one or more of the stages of the production and service method 100. For example, components or subassemblies corresponding to production process 108 may be fabricated or manufactured in a manner similar to components or subassemblies produced while the aircraft 102 is in service. Also, one or more apparatus embodiments, method embodiments, or a combination thereof may be utilized during the production stages 108 and 110, for example, by substantially expediting assembly of or reducing the cost of an aircraft 102. Similarly, one or more of apparatus embodiments, method embodiments, or a combination thereof may be utilized while the aircraft 102 is in service, for example and without limitation, to maintenance and service 116.

Although the apparatus of the invention and its method of use have been described by reference to a particular embodiment of the apparatus, it should be understood that modifications and variations to the apparatus and method could be made without departing from the intended scope of the claims appended hereto.

1. An aircraft window comprising:
a peripheral edge extending around the aircraft window;
a transparent layer extending across the aircraft window;
a layer of electromagnetic shielding material embedded inside the transparent layer; and,
an electrical conductor on the peripheral edge, the electrical conductor being connected in electric communication with the layer of electromagnetic shielding material.

2. The aircraft window of claim 1, further comprising:
the electrical conductor extending completely around the peripheral edge.

3. The aircraft window of claim 1, further comprising:
the electrical conductor being a foil tape that extends around the peripheral edge.

4. The aircraft window of claim 1, further comprising:
a pressure seal extending completely around the peripheral edge; and,
the electrical conductor extending over the pressure seal.

5. The aircraft window of claim 4, further comprising:
the electrical conductor being a foil tape.

6. The aircraft window of claim 1, further comprising:
the layer of electromagnetic shielding material having opposite first and second surfaces; and,
the transparent layer extending over and protecting the opposite first and second surfaces of the layer of electromagnetic shielding material.

7. The aircraft window of claim 1, further comprising:
the electrical conductor including a spring clip that is separate from the aircraft window, the spring clip having a first portion that engages against the electrical conductor and a second portion that is connectable to a portion of the aircraft on which the aircraft window is used when attaching the aircraft window to the portion of the aircraft, the spring clip thereby connecting the layer of electromagnetic shielding material in electric communication with the portion of the aircraft.

8. The aircraft window of claim 1, further comprising:
the transparent layer being one transparent layer of a plurality of transparent layers extending across the aircraft window.

9. An aircraft window comprising:
a peripheral edge extending around the aircraft window;
a plurality of transparent layers extending across the aircraft window to the peripheral edge;
one transparent layer of the plurality of transparent layers having a layer of electromagnetic shielding material embedded in the one transparent layer.

10. The aircraft window of claim 9, further comprising:
an electrically conductive material extending around the peripheral edge, the electrically conductive material being connected in electrical communication with the layer of electromagnetic shielding material.

11. The aircraft of claim 10, further comprising:
a portion of the layer of electromagnetic shielding material extending out of the one transparent layer; and,
the electrically conductive material being connected in electrical communication with the portion of the layer of electromagnetic shielding material.

12. The aircraft window of claim 10, further comprising:
the electrically conductive material extending completely around the peripheral edge.

13. The aircraft window of claim 10, further comprising:
the electrically conductive material being a foil tape.

14. The aircraft window of claim 10, further comprising:
a pressure seal extending around the peripheral edge; and,
the electrically conductive material extending over the pressure seal.

15. The aircraft window of claim 10, further comprising:
the electrically conductive material including a spring clip that is separate from the aircraft window, the spring clip having a first portion that engages against the aircraft window and a second portion that is connectable to a portion of the aircraft on which the aircraft window is used when attaching the aircraft window to the portion of the aircraft, the spring clip thereby connecting the layer of electromagnetic shielding material in electric communication with the portion of the aircraft.

16. A method of constructing an aircraft window comprising:
positioning a plurality of transparent layers side by side with peripheral edges of the plurality of transparent layers generally overlapping;
embedding a layer of electromagnetic shielding material in one transparent layer of the plurality of transparent layers;
securing together the peripheral edges of the plurality of transparent layers forming a peripheral edge of the aircraft window; and,
providing an electrical conductor on the peripheral edge of the aircraft window and coupling the electrical conductor in electric communication with the layer of electromagnetic shielding material.

17. The method of claim 16, further comprising:
positioning the electrical conductor completely around the peripheral edge of the aircraft window.

18. The method of claim 16, further comprising:
using a foil tape as the electrical conductor.

19. A method of using an aircraft window having a layer of electromagnetic shielding material embedded inside the window to dissipate electromagnetic radiation directed toward the aircraft window, the method comprising:
operating the aircraft in an environment where the aircraft window is subjected to electromagnetic radiation;
intercepting the electromagnetic radiation directed toward the aircraft window in the electromagnetic shielding material in the aircraft window; and,
conducting energy of the electromagnetic radiation intercepted by the layer of electromagnetic shielding material inside the window to a portion of the aircraft to which the window is attached to dissipate the energy in the portion of the aircraft.
